(19) United States
(12) Patent Application Publication
(10) Pub. No.: US 2024/0237224 A9
(43) Pub. Date: Jul. 11, 2024

(54) METHOD OF MANUFACTURING ELECTRONIC DEVICE

(71) Applicant: Samsung Display Co., LTD., Yongin-si (KR)

(72) Inventors: SHINYA ONOUE, Yongin-si (KR); EUNJOONG MUN, Yongin-si, Gyeonggi-do (KR); HYEON DEUK HWANG, Yongin-si (KR); JUNGWOOK KIM, Yongin-si (KR); HEECHANG KIM, Yongin-si (KR); Kyounghee PARK, Yongin-si (KR); JIYUN BANG, Yongin-si (KR)

(21) Appl. No.: 18/231,289

(22) Filed: Aug. 8, 2023

(30) Foreign Application Priority Data
Oct. 21, 2022 (KR) 10-2022-0136086

(51) Int. Cl. H05K 3/00; H05K 1/02; H05K 1/05; H05K 3/12

(52) U.S. Cl. CPC H05K 3/0014; H05K 1/0274; H05K 1/056; H05K 3/125; H05K 3/1283; H05K 2201/10128

(57) ABSTRACT

A method of manufacturing an electronic device includes providing a mold with a first opening defined therein and including a projection portion disposed in the first opening, forming, in the first opening, a first layer including a first material through an inkjet printing method, disposing the mold on a display panel in a way such that the first opening faces the display panel, and forming a display module by removing the mold. The display module is provided with a second opening defined therein and corresponding to the projection portion.

This application claims priority to Korean Patent Application No. 10-2022-0136086, filed on Oct. 21, 2022, and all the benefits accruing therefrom under 35 U.S.C. § 119, the content of which in its entirety is herein incorporated by reference.

### BACKGROUND

### 1. Field

The disclosure herein relates to a method of manufacturing an electronic device with improved reliability.

### 2. Description of the Related Art

Electronic devices, such as a smart phone or a tablet computer, may display an image through a display region of a display panel. Around the display region, a bezel region, for example, a non-display region is present. The bezel region is a region in which lines for transmitting input/output signals to a screen are disposed, and is covered by a separate case or is invisible to a user by adjusting the transparency of a window panel. Due to the bezel region, a display device may be configured in a greater size (i.e., area) than a display region. Various attempts are conducted to provide a user with the maximum size of a screen by reducing the bezel region within a limited size of an electronic device.

### SUMMARY

The disclosure provides a method of manufacturing an electronic device with improved reliability.

An embodiment of the invention provides a method of manufacturing an electronic device, the method including: providing a mold with a first opening defined therein and including a projection portion disposed in the first opening; forming, in the first opening, a first layer including a first material through an inkjet printing method; disposing the mold on a display panel in a way such that the first opening faces the display panel; and forming a display module by removing the mold, where the display module is provided with a second opening defined therein and corresponding to the projection portion.

In an embodiment, the first material may include a metal.

In an embodiment, the method may further include forming, on top of the first layer, a second layer including a second material different from the first material, through the inkjet printing method.

In an embodiment, the second material may include an epoxy-based resin.

In an embodiment, the method may further include attaching a digitizer film, which detects an external input, to the first layer, where the attaching of the digitizer film may be performed between the forming the first layer and the forming the second layer.

In an embodiment, the method may further include forming, on top of the second layer, a third layer including a third material different from the first material and the second material, through the inkjet printing method.

In an embodiment, the third material may include a colored material.

In an embodiment, the method may further include attaching a metal layer to the second layer.

In an embodiment, the metal layer may include copper.

In an embodiment, the method may further include disposing an electronic module in the second opening, where the disposing the electronic module may be performed after the forming the display module.

In an embodiment, the electronic module may include at least one selected from a camera module, an infrared module, and a fingerprint sensor.

In an embodiment, the forming of the first layer in the mold may include heating the mold at a predetermined temperature.

In an embodiment, the predetermined temperature may be in a range of about 80° C. to about 150° C.

In an embodiment, the heating of the mold may be performed for about 4 seconds to about 6 seconds.

In an embodiment, the forming of the first layer in the mold may include irradiating the mold with ultraviolet rays.

In an embodiment, a step may be formed on an inner surface of the mold defining the first opening.

In an embodiment, when viewed on a plane, a corner of the first opening may have a rounded shape.

In an embodiment, the projection portion may be provided in plurality, and a plurality of projection portions may be adjacent to each other.

In an embodiment of the invention, a method of manufacturing an electronic device includes: providing a mold having a first opening defined therein; forming, in the first opening, a first layer including a first material having conductivity through an inkjet printing method; forming, on top of the first layer, a second layer including a second material different from the first material through the inkjet printing method; and forming, on top of the second layer, a third layer including a third material including a colored material through the inkjet printing method; attaching the mold to a display panel in a way such that the third layer faces the display panel; and forming a display module by removing the mold.

In an embodiment, the mold may include a projection portion disposed in the first opening, a second opening corresponding to the projection portion may be defined in the display module, and the method further may include disposing an electronic module in the second opening.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic device according to an embodiment of the invention;

FIG. 2 is a schematic cross-section view of an electronic device according to an embodiment of the invention;

FIG. 3 is a flowchart illustrating a method of manufacturing an electronic device according to an embodiment of the invention;

FIG. 4A is a perspective view illustrating a mold according to an embodiment of the invention;

FIG. 4B is a cross-sectional view taken along line I-I′ of FIG. 4A according to an embodiment of the invention;

FIG. 5A is a perspective view illustrating a mold according to an embodiment of the invention;

FIG. 5B is a perspective view illustrating a mold according to an embodiment of the invention;

FIG. 6 is a cross-sectional view illustrating an operation of forming a layer in a mold according to an embodiment of the invention;

FIG. 7 is a cross-sectional view illustrating an operation of forming a layer in a mold according to an embodiment of the invention;

FIG. 8 is a cross-sectional view illustrating an operation of forming a layer in a mold according to an embodiment of the invention;

FIG. 9 is a cross-sectional view illustrating an operation of disposing a mold on a display panel according to an embodiment of the invention;

FIG. 10 is a cross-sectional view illustrating an operation of forming a display module according to an embodiment of the invention;

FIG. 11 is a cross-sectional view illustrating a method of manufacturing an electronic device according to an embodiment of the invention;

FIGS. 12A and 12B are cross-sectional views illustrating operations of stacking a layer in a mold according to an embodiment of the invention;

FIG. 12C is a cross-sectional view illustrating an operation of forming a display module according to an embodiment of the invention;

FIG. 13A is a cross-sectional view illustrating an operation of forming a layer in a mold according to an embodiment of the invention;

FIG. 13B is a cross-sectional view illustrating an operation of forming a display module according to an embodiment of the invention;

FIG. 14A is a cross-sectional view illustrating an operation of stacking a layer in a mold according to an embodiment of the invention;

FIG. 14B is a cross-sectional view illustrating an operation of forming a display module according to an embodiment of the invention;

FIG. 15A is a cross-sectional view illustrating an operation of forming a layer in a mold according to an embodiment of the invention;

FIG. 15B is a cross-sectional view illustrating an operation of forming a display module according to an embodiment of the invention;

FIG. 16A is a perspective view illustrating a mold according to an embodiment of the invention;

FIG. 16B is a plan view of an electronic device according to an embodiment of the invention; and

FIG. 16C is a cross-sectional view taken along line II-IP of FIG. 16B according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as “being on”, “connected to” or “coupled to” another element, it may be directly disposed on/connected/coupled to the other element, or intervening elements may be disposed therebetween.

Like reference numerals or symbols refer to like elements throughout. Also, in the drawings, the thickness, the ratio, and the dimension of the elements are exaggerated for effective description of the technical contents. The term “and/or” includes all combinations of one or more of the associated elements.

It will be understood that, although the terms first, second, etc. may be used herein to describe various elements, these elements should not be limited by these terms. These terms are only used to distinguish one element from another element. For example, a first element may be referred to as a second element, and similarly, a second element may also be referred to as a first element without departing from the scope of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Additionally, the terms such as “below”, “lower”, “above”, “upper”, and the like may be used herein to describe the relationship of the elements illustrated in the drawings. These terms have relative concepts and are described on the basis of the directions indicated in the drawings.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. Also, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

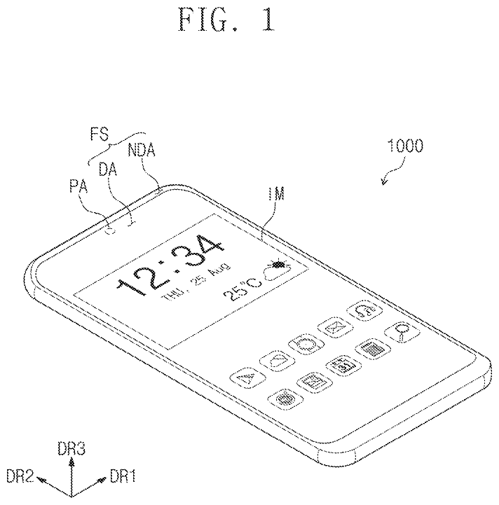

FIG. 1 is a perspective view of an electronic device according to an embodiment of the invention.

Referring to FIG. 1, an embodiment of an electronic device 1000 may have a shape including short sides extending in a first direction DR1 and long sides extending in a second direction DR2 crossing the first direction DR1. However, the shape of the electronic device 1000 is not limited thereto, and an electronic device 1000 having various shapes may be provided.

The electronic device 1000 according to an embodiment of the invention may be a large-sized electronic device such as a television, a monitor, etc., as well as a small- or medium-sized electronic device such as a mobile phone, a tablet computer, a car navigation system, a game console, and the like. These are merely presented as examples, and the electronic device 1000 may also be employed in other electronic devices without departing from the scope of the invention.

The electronic device 1000 may display an image IM on a display surface FS, which is parallel to each of the first direction DR1 and the second direction DR2 or on a plane defined by the first direction DR1 and the second direction DR2, toward a third direction DR3 crossing the first direction DR1 and the second direction DR2. The display surface FS on which the image IM is displayed may correspond to a front (or upper) surface of the electronic device 1000.

The display surface FS of the electronic device 1000 may be separated as (or divided into) a plurality of regions. A display region DA and a non-display region NDA may be defined in the display surface FS.

The display region DA may be a region in which the image IM is displayed, and the image IM may be visible to a user through the display region DA. A shape of the display region DA may be substantially defined by the non-display region NDA. However, this is exemplarily illustrated, the non-display region NDA may be disposed adjacent to only one side of the display region DA or may be omitted. The electronic device 1000 according to an embodiment of the invention may be variously modified, and is not limited to any one embodiment.

The non-display region NDA may be a region which is adjacent to the display region DA, and on which the image IM is not be displayed. A bezel region of the electronic device 1000 may be defined by the non-display region NDA.

The non-display region NDA may surround the display region DA. However, this is exemplarily illustrated, the non-display region NDA may be adjacent to only a portion of the edges of the display region DA, and an embodiment of the invention is not limited thereto.

A sensor region PA may be defined in the display region DA. The sensor region PA may overlap an electronic module to be described later. The electronic device 1000 may receive, through the sensor region PA, external signals used for the electronic module or may provide, to the outside, signals output from the electronic module. According to an embodiment of the invention, since the sensor region PA is defined in the display region DA, a region separately provided for the sensor region PA may be omitted in the non-display region NDA. Accordingly, the area of the bezel region may be reduced.

FIG. 1 illustrates an embodiment where a single sensor region PA is provided, but the number of sensor regions PA according to an embodiment of the invention is not limited thereto. Alternatively, a plurality of sensor regions PA, for example, two or more sensor regions PA may be defined.

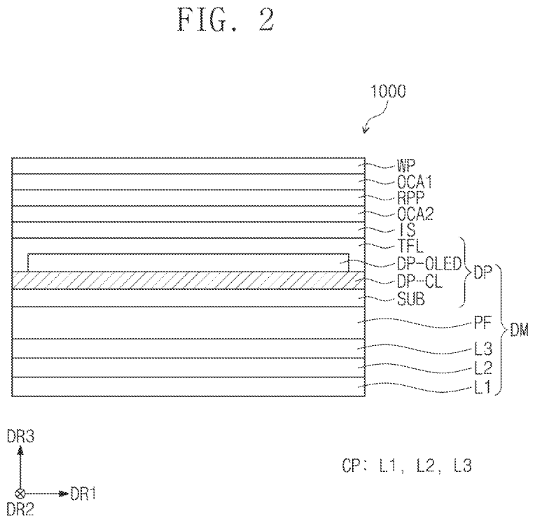

FIG. 2 is a schematic cross-section view of an electronic device according to an embodiment of the invention.

Referring to FIG. 2, an embodiment of the electronic device 1000 may include a window WP, a plurality of adhesive layers OCA1 and OCA2, an optical film RPP, and a display module DM.

The window WP may form the exterior of the electronic device 1000. The window WP may be a component which protects internal components of the electronic device 1000 against an external impact and substantially provides the display region DA (see FIG. 1) of the electronic device 1000. In an embodiment, for example, the window WP may include a glass substrate, a sapphire substrate, a plastic film, or like. The window WP may have a single- or multi-layered structure. In an embodiment, for example, the window WP may have a stacked structure in which a plurality of plastic films are bonded with an adhesive, or a stacked structure in which a glass substrate and a plastic film are bonded to each other with an adhesive therebetween.

The adhesive layer OCA1 may be disposed under the window WP. The adhesive layer OCA1 may bond the window WP and the optical film RPP. The adhesive layer OCA1 may include a conventional bonding agent or an adhesive agent known in the art. In an embodiment, for example, the adhesive layer OCA1 may be an optically clear adhesive film, an optically clear resin, or a pressure sensitive adhesive film.

The optical film RPP may be disposed below the window WP. The optical film RPP may reduce the reflectance for natural (or external) light (e.g., sunlight) incident from above the window WP.

The optical film RPP may reduce the external reflectance of the display module DM for the light incident on the display module DM. Although not illustrated, the optical film RPP may include at least one selected from an anti-reflection film, a polarizing film, a color filter, and a gray filter.

The adhesive layer OCA2 may be disposed under the optical film RPP. The adhesive layer OCA2 may bond the optical film RPP and the display module DM. The adhesive layer OCA1 and the adhesive layer OCA2 may include substantially the same material.

The display module DM may be disposed below the optical film RPP. The display module DM may include a sensor layer IS, a display panel DP, a protective layer PF, and a lower member layer CP.

The sensor layer IS may obtain coordinate information on an external input. The sensor layer IS according to an embodiment of the invention may be directly disposed on one surface of the display panel DP. In an embodiment, for example, the sensor layer IS may be integrated with the display panel DP in an on-cell manner. In such an embodiment, the sensor layer IS and the display panel DP may be manufactured through a continuous process. However an embodiment of the invention is not limited thereto, and alternatively, the sensor layer IS may be manufactured through an additional process and adhered to the display panel DP. The sensor layer IS may include a touch panel.

The display panel DP may be disposed under the sensor layer IS. The display panel DP may be configured to substantially generate the image IM (see FIG. 1). The display panel DP may be a light-emitting display panel, but is not particularly limited. In an embodiment, for example, the display panel DP may include an organic light-emitting display panel, a quantum dot display panel, a micro-light emitting diode (LED) display panel, or a nano-LED display panel. The display panel DP may include a base layer SUB, a display circuit layer DP-CL, an image displaying layer DP-OLED, and a thin film encapsulation layer TFL. This will be described later in greater detail.

The protective layer PF may be disposed under the display panel DP. The protective layer PF may protect a lower surface of the display panel DP. The protective layer PF may include polyethylene terephthalate (PET). However, the material of the protective layer PF is not particularly limited thereto.

The lower member layer CP may be disposed under the protective layer PF. The lower member layer CP may include a first layer L1, a second layer L2, and a third layer L3 which are sequentially formed or stacked in the third direction DR3.

The third layer L3 may be disposed under the protective layer PF. The third layer L3 may be a colored layer having low light transmittance. In an embodiment, for example, the third layer L3 may be black. The third layer L3 may absorb the light incident thereon, such that the components disposed below the third layer L3 may be invisible to a user when the electronic device 1000 is viewed from above the window WP. The third layer L3 may include at least one selected from a silicone-based resin, an acrylic resin, and an epoxy-based resin.

The third layer L3 may have adhesiveness through ultraviolet (UV) curing to be described later. Due to the adhesiveness, the third layer L3 may be bonded to the protective layer PF. Alternatively, an adhesive layer may be further disposed between the third layer L3 and the protective layer PF. The adhesive layer may include a conventional bonding agent or an adhesive agent known in the art.

The second layer L2 may be disposed under the third layer L3. The second layer L2 may function to alleviate pressure applied from the outside. That is, the second layer L2 may improve the impact resistance of the electronic device 1000. The second layer L2 may include at least one selected from a silicone-based resin, an acrylic resin, and an epoxy-based resin.

The first layer L1 may be disposed under the second layer L2. The first layer L1 may induce the release of the heat generated from the display panel DP. The first layer L1 may prevent electromagnetic interference (EMI). In an embodiment, for example, the first layer L1 may include a conductive material.

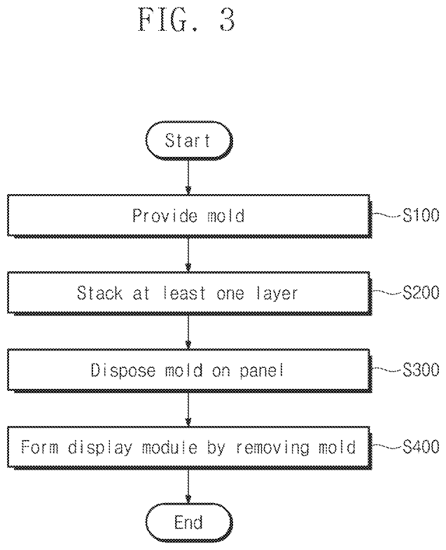

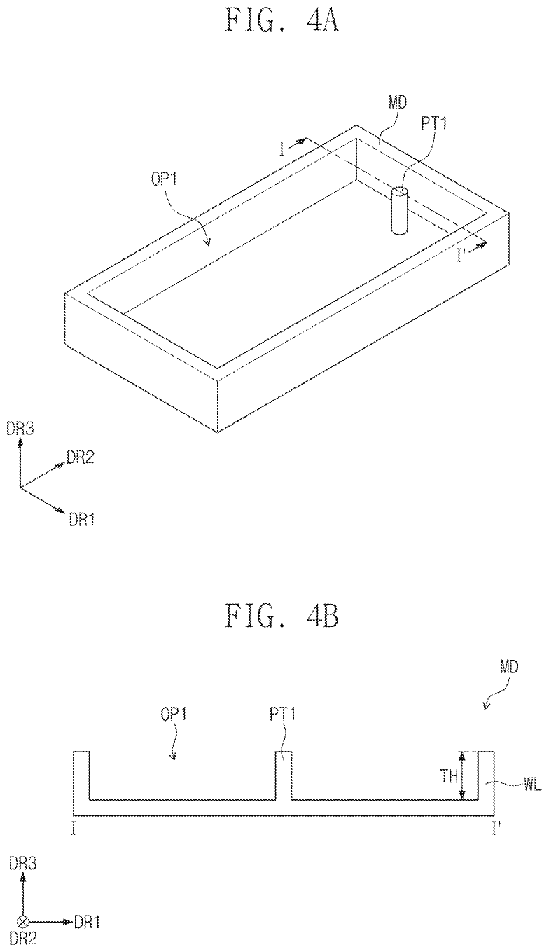

FIG. 3 is a flowchart illustrating a method of manufacturing an electronic device according to an embodiment of the invention, FIG. 4A is a perspective view illustrating a mold according to an embodiment of the invention, and FIG. 4B is a cross-sectional view taken along line of FIG. 4A according to an embodiment of the invention.

Referring to FIGS. 3 to 4B, in the method of manufacturing the electronic device 1000 (see FIG. 1), a mold MD may be provided (S100). The mold MD may have a flat surface which has short sides extending in the first direction DR1 and long sides extending in the second direction DR2. The mold MD may have a plurality of walls WL respectively protruding along the short sides and the long sides in the third direction DR3.

The plurality of walls WL may each have a first thickness TH. The first thickness TH and the thickness of the lower member layer CP (see FIG. 2) may be substantially the same as each other. In an embodiment, for example, the first thickness TH may be about 500 micrometers (μm).

A first opening OP1 may be defined in the mold MD by the plurality of walls. The first opening OP1 may have various shapes corresponding to a shape of the display panel DP (see FIG. 2).

The mold MD may include at least one projection portion PT1 disposed in the first opening OP1. The projection portion PT1 may protrude in the third direction DR3. The height of the projection portion PT1 may be the same as the first thickness TH of each of the plurality of walls WL. However, this is merely an example, and the projection portion PT1 according to an alternative embodiment of the invention may have various heights based on a shape of the lower member layer CP (see FIG. 2) appropriate for the electronic device 1000 (see FIG. 1). In an embodiment, as shown in FIG. 4A, the mold MB may include a single projection portion PT1 having a cylindrical shape, for example.

When viewed on a plane (or in the third direction DR3), the projection portion PT1 may overlap the sensor region PA (see FIG. 1).

According to an embodiment of the invention, a shape of the lower member layer CP (see FIG. 2) may be determined based on a shape of the first opening OP1, such that the lower member layer CP (see FIG. 2) appropriate for the electronic device 1000 (see FIG. 1) may be effectively manufactured by controlling the shape of the mold MD. Therefore, the manufacturing flexibility of the lower member layer CP (see FIG. 2) may be improved.

In addition, according to an embodiment of the invention, the lower member layer CP (see FIG. 2) may be manufactured using the mold MD. A shape of outer curvature, a hole, an edge, or the like of the lower member layer CP (see FIG. 2) may be formed to correspond to a shape of the mold MD. Therefore, the manufacturing flexibility of the lower member layer CP (see FIG. 2) may be improved.

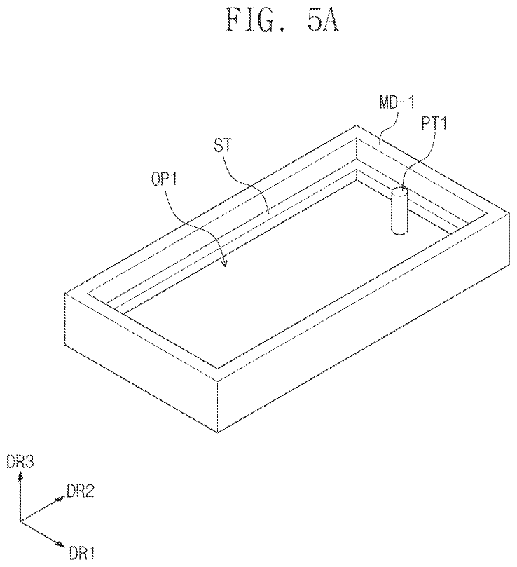

FIG. 5A is a perspective view illustrating a mold according to an embodiment of the invention.

Referring to FIGS. 3 and 5A, a step ST may be formed on at least one inner surface of the mold defining a first opening OP1.

According to an embodiment of the invention, since a mold MD-1 is easily manufactured according to a shape of the display panel DP, the lower member layer CP (see FIG. 2) appropriate for the electronic device 1000 (see FIG. 1) may be provided. In an embodiment, for example, when a space is desired to insert an electronic module into the electronic device 1000 (see FIG. 1), a mold may be manufactured in a way such that a step ST is formed to define the space in the lower member layer CP (see FIG. 2). Therefore, the method of manufacturing the electronic device 1000 (see FIG. 1) with improved reliability may be provided.

FIG. 5B is a perspective view illustrating a mold according to an embodiment of the invention.

Referring to FIGS. 3 and 5B, when viewed on a plane or in the third direction DR3, at least one corner ED of the mold defining a first opening OP1 may have a rounded shape. The first opening OP1 may have various shapes according to a shape of the display panel DP (see FIG. 2). In such an embodiment where at least one corner has a rounded shape, the first opening OP1 of a mold MD-2 may be formed so that the corner ED of the first opening OP1 corresponding to the corner on a plane has a rounded shape when the display panel DP (see FIG. 2) is viewed from the top (or in the third direction DR3) to be identical or similar to the shape of the display panel DP (see FIG. 2).

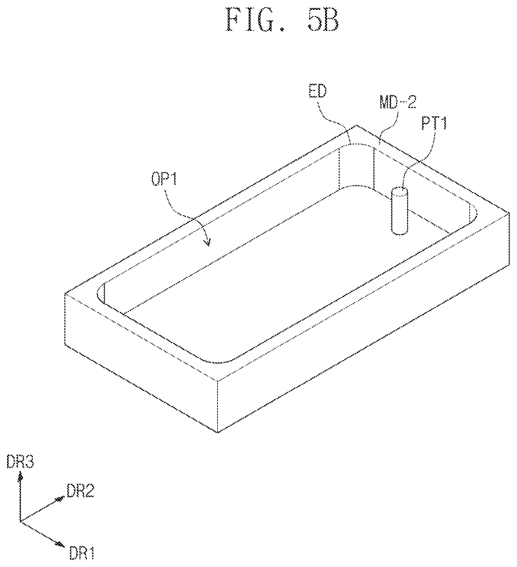

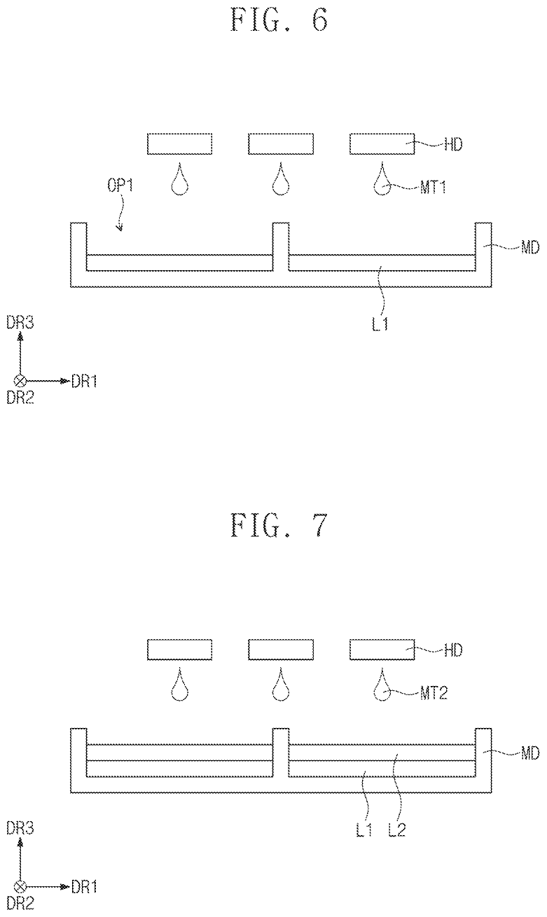

FIG. 6 is a cross-sectional view illustrating an operation of forming (or stacking) a layer in a mold according to an embodiment of the invention.

Referring to FIGS. 3 and 6, at least one first layer L1 may be formed or stacked in the first opening OP1 of the mold MD (S200).

A solution or ink including or containing a first material MT1 may be provided into the first opening OP1. The solution including or containing the first material MT1 may be provided through an inkjet process. During the inkjet process, an inkjet head HD may provide the solution including or containing the first material MT1 into the first opening OP1.

The inkjet head HD may include a nozzle for providing the solution. The inkjet head HD may be provided in plurality. The plurality of inkjet heads HD may be arranged in the first direction DR1 and spray the solution to the first opening OP1 while moving in the second direction DR2. However, this is merely an example, and a single inkjet head HD according to an embodiment of the invention may be provided and spray the solution to the first opening OP1 while moving in the first direction DR1 and the second direction DR2.

The first material MT1 may include a metal. In an embodiment, for example, a solution including or containing the first material MT1 may be a silicone-based resin, an acrylic resin, or an epoxy-based resin which include a metal.

After the inkjet head HD provides the solution including or containing the first material MT1 into the first opening OP1, the solution may be cured. As the solution is cured, the first layer L1 may be formed.

During the curing of the solution, the mold MD may be heated at a predetermined temperature. The predetermined temperature may be in a range of about 80° C. to about 150° C. Here, the mold MD may be heated at the predetermined temperature for about 4 seconds to about 6 seconds.

In a case where a film is directly applied on the display panel DP (see FIG. 2) instead of manufacturing the lower member layer CP (see FIG. 2) using the mold MD and then attaching the layer to the display panel DP (see FIG. 2), thermal curing may be performed at a low temperature to minimize the thermal effect on the display panel DP (see FIG. 2) during the heating for the applied film to be cured. In this case, for example, the lower member layer CP (see FIG. 2) may be heated at a temperature of about 30° C. to about 80° C. to be cured. However, according to an embodiment of the invention, the first layer L1 may be formed using the mold MD, and then the lower member layer CP (see FIG. 2) including the first layer L1 may be attached to the display panel DP (see FIG. 2). Accordingly, in such an embodiment, the first layer L1 disposed in the mold MD may be cured at a high temperature. The curing rate of the first layer L1 may be increased, that is, the curing may become faster. That is, the tact time for forming the first layer L1 may be reduced. Here, tact time means the manufacturing time per unit product to achieve the daily production goal.

In such an embodiment, during the curing of the solution, the mold MD may be irradiated with UV rays. This may be referred to as an UV curing.

In a case where a film is directly applied on the display panel DP (see FIG. 2) instead of manufacturing the lower member layer CP (see FIG. 2) using the mold MD and then, attaching the layer to the display panel DP (see FIG. 2), during UV irradiation for the applied film to be cured, UV curing may be performed with low-intensity light to minimize the UV effect on the display panel DP (see FIG. 2). However, according to an embodiment of the invention, the first layer L1 may be formed using the mold MD, and then the lower member layer CP (see FIG. 2) including the first layer L1 may be attached to the display panel DP (see FIG. 2). In such an embodiment, the first layer L1 disposed in the mold MD may be cured with high-intensity UV light. The curing rate of the first layer L1 may be increased, that is, the curing may become faster. That is, the tact time for forming the first layer L1 may be reduced.

In a case where the first layer L1 is formed not through an inkjet process but a film application process, a curling phenomenon may occur due to the diameter of a winding core of a film provided in a cylindrical shape. When the film is cut according to a shape of the display panel DP (see FIG. 2), burrs may be caused. Alternatively, when the film is attached to the display panel DP (see FIG. 2), bubbles, curling, and/or inclusion of a foreign substance may be caused. However, according to an embodiment of the invention, defects, which may occur during the application process may be effectively prevented by performing the inkjet process. Therefore, the electronic device 1000 (see FIG. 1) with improved reliability may be provided.

FIG. 7 is a cross-sectional view illustrating an operation of forming a layer in a mold according to an embodiment of the invention.

Referring to FIGS. 3 and 7, a second layer L2 may be formed or stacked in the first opening OP1 of the mold MD (S200). The second layer L2 may be stacked on top of the first layer L1. The second layer L2 and the first layer L1 may be formed through the same process.

A solution or ink including or containing a second material MT2 different from the first material MT1 (see FIG. 6) may be provided into the first opening OP1. The solution including or containing the second material MT2 may be provided through an inkjet process.

The second material MT2 may include a silicone-based resin, an acrylic resin, or an epoxy-based resin.

After the inkjet head HD provides the solution including or containing the second material MT2 into the first opening OP1, the solution may be cured. As the solution is thermally cured or cured by UV irradiation, the second layer L2 may be formed.

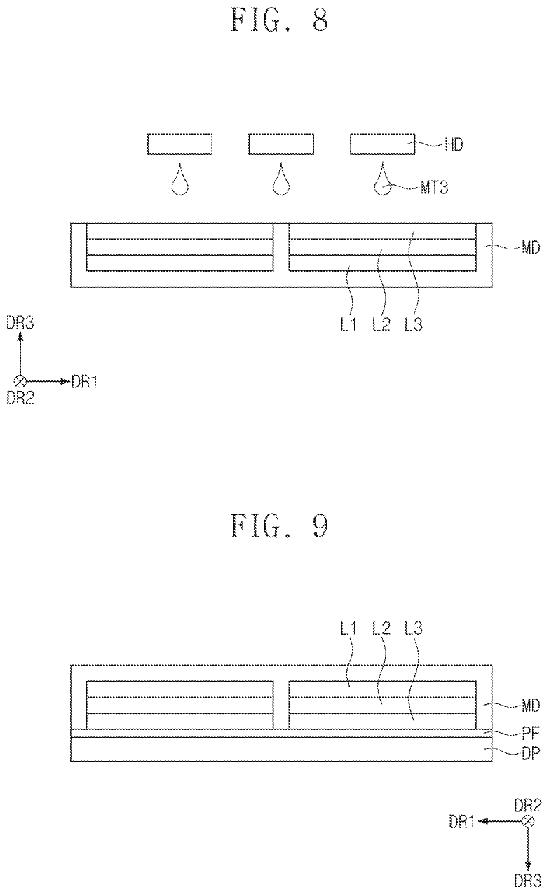

FIG. 8 is a cross-sectional view illustrating an operation of forming a layer in a mold according to an embodiment of the invention.

Referring to FIGS. 3 and 8, a third layer L3 may be formed or stacked in the first opening OP1 of the mold MD (S200). The third layer L3 may be stacked on top of the second layer L2. The third layer L3 and the first layer L1 may be formed through a same process as each other.

A solution or ink including or containing a third material MT3 different from the first material MT1 (see FIG. 6) and the second material MT2 (see FIG. 7) may be provided into the first opening OP1. The third material MT3 may include a colored material. In an embodiment, for example, the solution including or containing the third material MT3 may be a silicone-based resin, an acrylic resin, or an epoxy-based resin which include a colored material.

After the inkjet head HD provides the solution including or containing the third material MT3 into the first opening OP1, the solution may be thermally cured or cured by UV irradiation. As the solution is cured, the third layer L3 may be formed.

FIG. 9 is a cross-sectional view illustrating an operation of disposing a mold on a display panel according to an embodiment of the invention.

Referring to FIGS. 3 and 9, the mold MD may be disposed on a display panel DP so that the first opening OP1 faces the display panel DP (S300).

The third layer L3 may have adhesiveness through UV curing. Due to the adhesiveness, the third layer L3 may be bonded with the protective layer PF. Alternatively, an adhesive layer may be further disposed between the third layer L3 and the protective layer PF. The adhesive layer may include a conventional bonding agent or an adhesive agent known in the art.

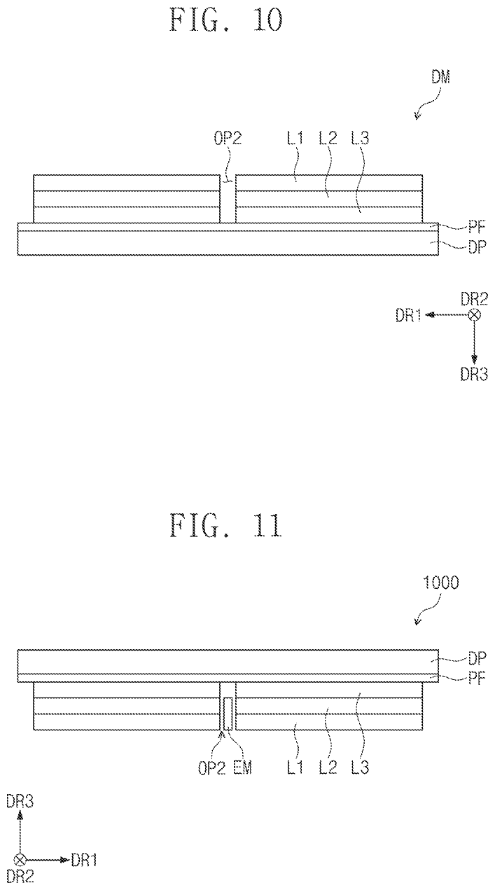

FIG. 10 is a cross-sectional view illustrating an operation of forming a display module according to an embodiment of the invention.

Referring to FIGS. 3 and 10, after the third layer L3 is bonded with the protective layer PF, the mold MD may be removed. As the mold MD is removed, the display module DM may be formed (S400).

At least one second opening OP2 respectively corresponding to the at least one projection portion PT1 (see FIG. 4A) of the mold MD (see FIG. 4A) may be defined in the display module DM.

When viewed from the top or in the third direction DR3, the second opening OP2 may overlap the sensor region PA (see FIG. 1).

In a case where the first to third layers L1, L2, and L3 are formed not through an inkjet process but a film application process, the second opening OP2 may be formed through a cutting process. In this case, it may be difficult to control the thicknesses of the first to third layers L1, L2, and L3 adjacent to the second opening OP2. However, according to an embodiment of the invention, the first to third layers L1, L2, and L3 are formed or stacked through the inkjet process using the mold MD (see FIG. 4A) and the first to third layers L1, L2, and L3 are formed by removing the mold MD (see FIG. 4A). That is, in the method of manufacturing the electronic device 1000 (see FIG. 1) according to an embodiment of the invention, the cutting process for forming the second opening OP2 may be omitted. The first to third layers L1, L2, and L3 may each have improved thickness uniformity. Therefore, the method of manufacturing the electronic device 1000 (see FIG. 1) with improved reliability may be provided.

FIG. 11 is a cross-sectional view illustrating a method of manufacturing an electronic device according to an embodiment of the invention.

Referring to FIG. 11, the electronic device 1000 may further include an electronic module EM. The electronic module EM may be disposed in a second opening OP2. The electronic module EM may be disposed after the display module DM is formed. The electronic module EM may be disposed below a display panel DP.

The electronic module EM may be a camera module, an infrared module, or a fingerprint sensor. In an embodiment, for example, where the electronic module EM is the camera module, a hole may be defined in the display panel DP in a region overlapping the electronic module EM. When viewed from the top or in the third direction DR3, the electronic module EM may overlap the sensor region PA (see FIG. 1).

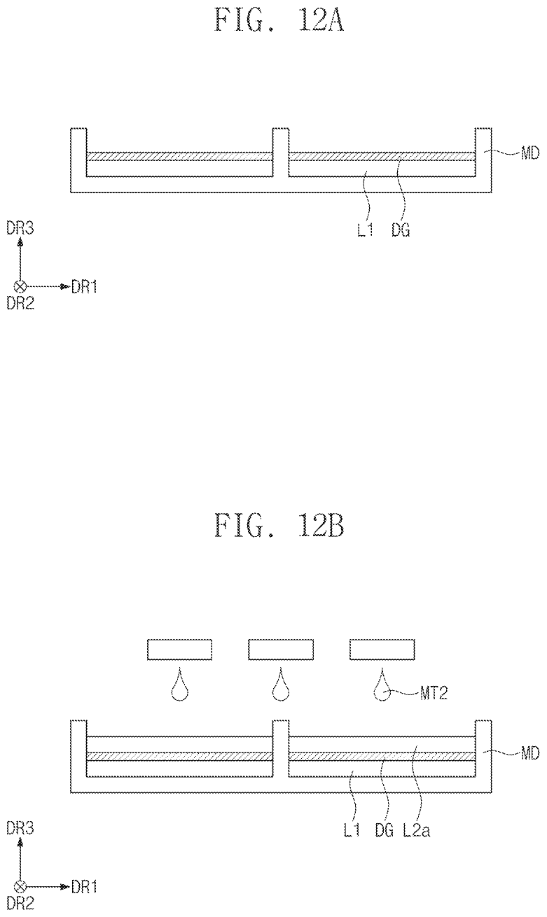

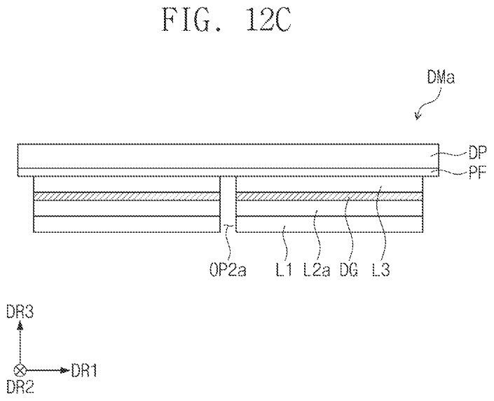

FIGS. 12A and 12B are cross-sectional views illustrating operations of forming a layer in a mold according to an embodiment of the invention, and FIG. 12C is a cross-sectional view illustrating an operation of forming a display module according to an embodiment of the invention. In the description of FIGS. 12A to 12C, the same or like reference numerals or symbols are used for the same or like components as those described above with reference to FIGS. 6 and 10, and any repetitive detailed description thereof will be omitted.

Referring to FIGS. 12A to 12C, a first layer L1 may be formed or stacked in the first opening OP1 through an inkjet process.

The electronic device 1000 (see FIG. 1) may further include a digitizer film DG. The digitizer film DG may detect an external input detected by the electronic device 1000 (see FIG. 1), specifically, an external input different from an external input detected by the sensor layer IS (see FIG. 2). The digitizer film DG may detect an external input by an input device, and the sensor layer IS (see FIG. 2) may detect an external input detected by a part of a user's body. In an embodiment, for example, the input device may include an electromagnetic pen, and the part of a user's body may include the user's hand.

The digitizer film DG may include a plurality of coils. The digitizer film DG may detect an external input through an electro-magnetic resonance (EMR) method. In the EMR method, a magnetic field is generated from a resonant circuit formed in the input device, and the oscillating magnetic field induces a signal to the plurality of coils included in the digitizer film DG, so that a position of the input device may be detected through the signal induced to the coils.

The digitizer film DG may be attached onto the first layer L1. When viewed from the top or in the third direction DR3, a shape of the digitizer film DG may be defined based on a shape of the first opening OP1.

A second layer L2a may be formed or stacked in the first opening OP1 of the mold MD. A solution or ink including or containing the second material MT2 may be provided on the digitizer film DG. The second layer L2a may be formed or stacked through an inkjet process.

That is, in such an embodiment, the attaching of the digitizer film DG may be performed between the forming of the first layer L1 and the forming of the second layer L2.

A second opening OP2a corresponding to the projection portion PT1 (see FIG. 4A) may be defined in a display module DMa. That is, the second opening OP2a may be defined through the first layer L1, the digitizer film DG, the second layer L2a, and the third layer L3 in the third direction DR3. The electronic module EM (see FIG. 11) may be disposed in the second opening OP2a.

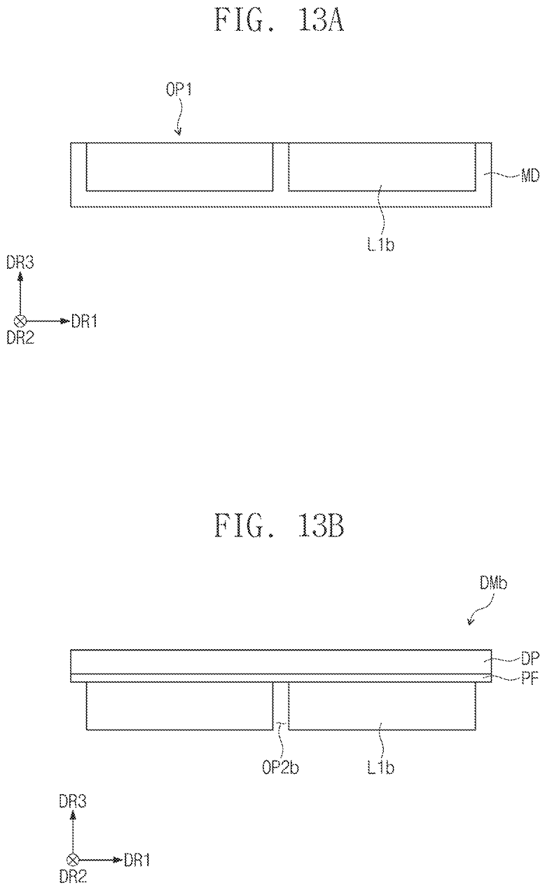

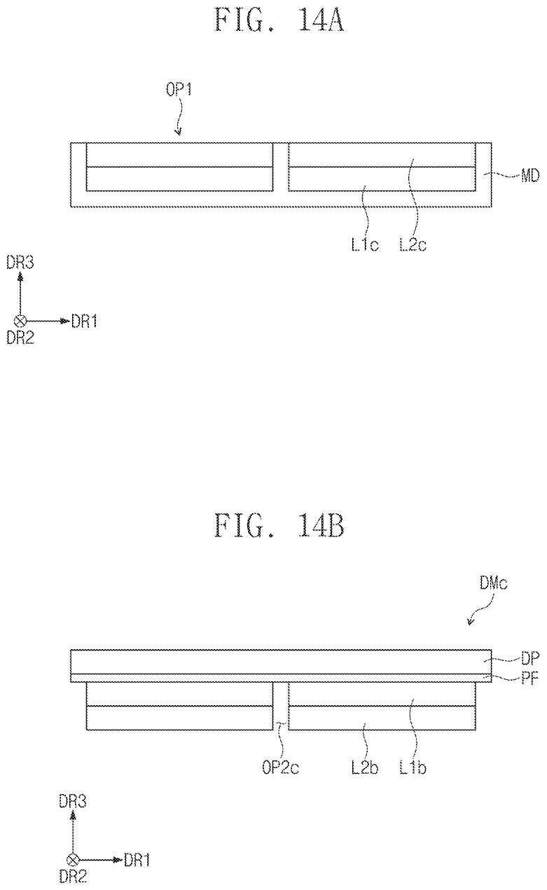

FIG. 13A is a cross-sectional view illustrating an operation of forming a layer in a mold according to an embodiment of the invention, and FIG. 13B is a cross-sectional view illustrating an operation of forming a display module according to an embodiment of the invention. In the description of FIGS. 13A and 13B, the same or like reference numerals or symbols are used for the same or like components as those described above with reference to FIGS. 6 and 10, and any repetitive detailed description thereof will be omitted.

Referring to FIGS. 13A and 13B, a first layer L1b may be formed or stacked in the first opening OP1 through an inkjet process.

A solution or ink including or containing a first material may be provided into the first opening OP1. The first material may include a material having functions of light blocking, impact resistance, heat dissipation, or electromagnetic interference prevention.

As the first material is cured, the first layer L1b may be formed. The first layer L1b may have adhesiveness through the curing. Due to the adhesiveness, the first layer L1b may be bonded with the protective layer PF. Alternatively, an adhesive layer may be further disposed between the first layer L1b and the protective layer PF. The adhesive layer may include a conventional bonding agent or an adhesive agent known in the art.

A second opening OP2b corresponding to the projection portion PT1 (see FIG. 4A) may be defined in a display module DMb. That is, the second opening OP2b may be defined through the first layer L1b in the third direction DR3. The electronic module EM (see FIG. 11) may be disposed in the second opening OP2b. That is, the lower member layer CP (see FIG. 2) according to an embodiment of the invention may be a single layer.

FIG. 14A is a cross-sectional view illustrating an operation of forming a layer in a mold according to an embodiment of the invention, and FIG. 14B is a cross-sectional view illustrating an operation of forming a display module according to an embodiment of the invention. In the description of FIGS. 14A and 14B, the same or like reference numerals or symbols are used for the same or like components as those described above with reference to FIGS. 6 and 10, and any repetitive detailed description thereof will be omitted.

Referring to FIGS. 14A and 14B, a first layer L1c may be formed or stacked in the first opening OP1 through an inkjet process.

A solution or ink including or containing a first material may be provided into the first opening OP1. The first material may include a material having functions of heat dissipation or electromagnetic interference prevention.

As the first material is thermally cured or cured by UV irradiation, the first layer L1c may be formed.

A second layer L2c may be formed or stacked in the first opening OP1 through an inkjet process. The second layer L2c may be disposed on top of the first layer L1c.

A solution or ink including or containing a second material may be provided into the first opening OP1. The second material may include a material having functions of light blocking or impact resistance.

As the second material is thermally cured or cured by UV irradiation, the second layer L2c may be formed. The second layer L2c may have adhesiveness through the curing. Due to the adhesiveness, the second layer L2c may be bonded with the protective layer PF. Alternatively, an adhesive layer may be further disposed between the second layer L2c and the protective layer PF. The adhesive layer may include a conventional bonding agent or an adhesive agent known in the art.

A second opening OP2c corresponding to the projection portion PT1 (see FIG. 4A) may be defined in a display module DMc. That is, the second opening OP2c may be defined through the first layer L1b in the third direction DR3. The electronic module EM (see FIG. 11) may be disposed in the second opening OP2c. That is, the lower member layer CP (see FIG. 2) according to an embodiment of the invention may be composed of two layers.

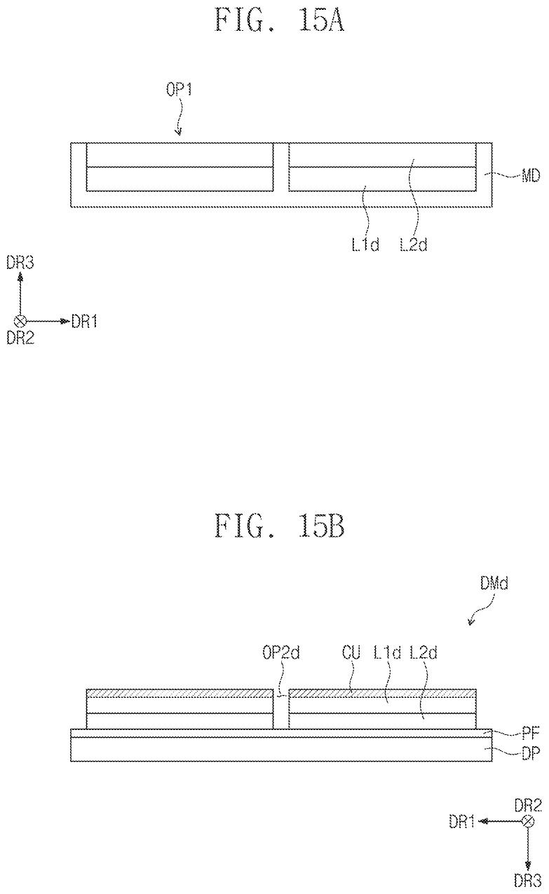

FIG. 15A is a cross-sectional view illustrating an operation of forming a layer in a mold according to an embodiment of the invention, and FIG. 15B is a cross-sectional view illustrating an operation of forming a display module according to an embodiment of the invention. In the description of FIGS. 15A and 15B, the same or like reference numerals or symbols are used for the same or like components as those described above with reference to FIGS. 6 and 10, and any repetitive detailed description thereof will be omitted.

Referring to FIGS. 15A and 15B, a first layer L1d may be formed or stacked in the first opening OP1 through an inkjet process.

A solution or ink including or containing a first material may be provided into the first opening OP1. The first material may include a material having an impact resistance function.

As the first material is thermally cured or cured by UV irradiation, the first layer L1d may be formed.

A second layer L2d may be formed or stacked in the first opening OP1 through an inkjet process. The second layer L2d may be disposed on top of the first layer L1d.

A solution or ink including or containing a second material may be provided into the first opening OP1. The second material may include a material having a light blocking function.

As the second material is thermally cured or cured by UV irradiation, the second layer L2d may be formed. The second layer L2d may have adhesiveness through the curing. Due to the adhesiveness, the second layer L2d may be bonded with the protective layer PF. Alternatively, an adhesive layer may be further disposed between the second layer L2d and the protective layer PF. The adhesive layer may include a conventional bonding agent or an adhesive agent known in the art.

A metal layer CU may be attached onto the second layer L2d. The metal layer CU may have conductivity. The metal layer CU may include copper. In an embodiment, for example, the metal layer CU may be a copper (Cu) tape. In such an embodiment, the metal layer CU may have functions of heat dissipation and electromagnetic interference prevention.

A second opening OP2d corresponding to the projection portion PT1 (see FIG. 4A) may be defined in a display module DMd. That is, the second opening OP2d may be defined through the first layer L1b in the third direction DR3. The electronic module EM (see FIG. 11) may be disposed in the second opening OP2d.

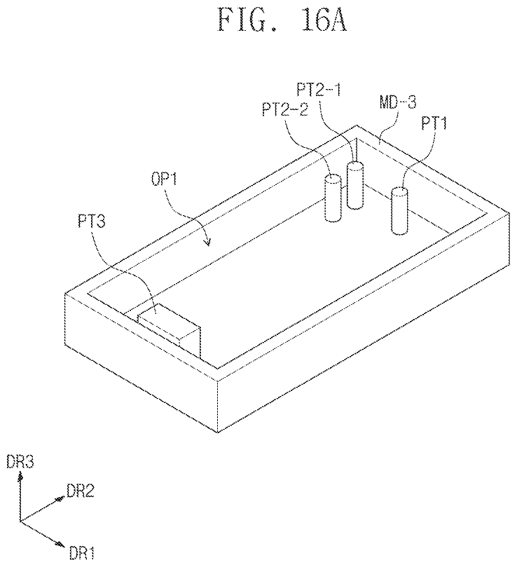

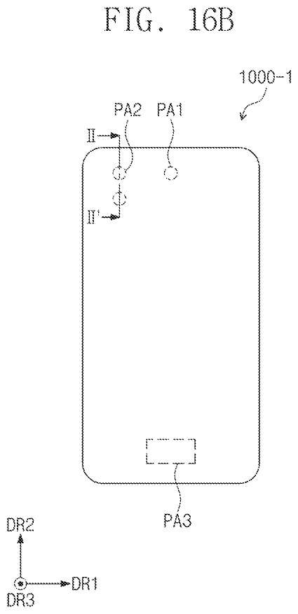

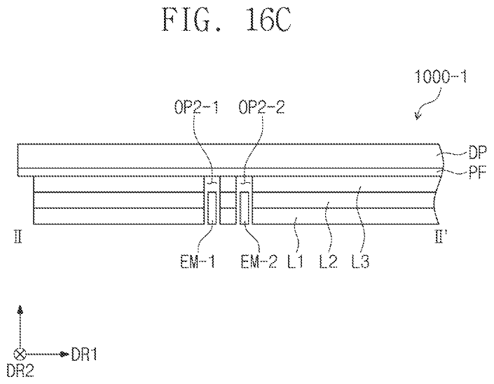

FIG. 16A is a perspective view illustrating a mold according to an embodiment of the invention, FIG. 16B is a plan view of an electronic device according to an embodiment of the invention, and FIG. 16C is a cross-sectional view taken along line II-II′ of FIG. 16B according to an embodiment of the invention.

Referring to FIGS. 16A to 16C, a mold MD-3 may include a plurality of projection portions PT1, PT2-1, PT2-2, and PT3 disposed in the first opening OP1.

The plurality of projection portions PT1, PT2-1, PT2-2, and PT3 may include the first projection portion PT1, the second projection portions PT2-1 and PT2-2, and the third projection portion PT3.

A first sensor region PA1, a second sensor region PA2, and a third sensor region PA3 may be defined in an electronic device 1000-1.

The first projection portion PT1 may be disposed in a region corresponding to the first sensor region PA1. A first electronic module may be disposed below the first sensor region PA1. The first electronic module may include a camera module. The camera module may capture an image of the outside.

The second projection portions PT2-1 and PT2-2 may be respectively disposed in regions corresponding to the second sensor regions PA2. The second projection portions PT2-1 and PT2-2 may be disposed to be adjacent to each other. Second electronic modules EM-1 and EM-2 may be respectively disposed below the second sensor regions PA2.

The second electronic modules EM-1 and EM-2 may each include an infrared module. The second electronic modules EM-1 and EM-2 may include a light-emitting module and a light-receiving module. The light-emitting module may generate and output light. In an embodiment, for example, the light-emitting module may output infrared light. The light-emitting module may include an LED element. The light-receiving module may detect infrared light. The light-receiving module may include a complementary metal-oxide-semiconductor (CMOS) sensor. The infrared light generated by the light-emitting module is output, the output light is then reflected on an external subject (for example, a user's finger or face), and the reflected infrared light may be incident on the light-receiving module.

The third projection portion PT3 may be disposed in a region corresponding to the third sensor region PA3. A third electronic module may be disposed below the third sensor region PA3. The third electronic module may include a fingerprint sensor.

When the mold MD-3 is removed and the electronic device 1000-1 is manufactured, a first second opening OP2-1 and a second second opening OP2-2 may be defined by the second projection portions PT2-1 and PT2-2.

One of the second electronic modules EM-1 and EM-2 may be disposed in the first second opening OP2-1. The other of the second electronic modules EM-1 and EM-2 may be disposed in the second second opening OP2-2.

The second electronic modules EM-1 and EM-2 may be disposed to be adjacent to each other.

In a case where the first to third layers L1, L2, and L3 are formed not through an inkjet process but a film application process, the first second opening OP2-1 and the second second opening OP2-2 may be formed through a cutting process. In this case, it may be difficult to control the thicknesses of the first to third layers L1, L2, and L3 disposed between the first second opening OP2-1 and the second second opening OP2-2. As the interval between the first second opening OP2-1 and the second second opening OP2-2 is narrower, the thickness control of the first to third layers L1, L2, and L3 may be more difficult. In this case, for example, the thicknesses of the first to third layers L1, L2, and L3 disposed between the first second opening OP2-1 and the second second opening OP2-2 may be smaller than the normal thickness. However, according to an embodiment of the invention, the first to third layers L1, L2, and L3 may each be formed or stacked with a uniform thickness through the inkjet process using the mold MD-3. Therefore, the electronic device 1000-1 with improved reliability may be provided.

According to embodiments of the invention, as described above, a first layer may be formed using a mold, and then a lower member layer including the first layer may be attached to a display panel. The first layer disposed in the mold may be cured at a high temperature or by being irradiated with high-intensity UV light. The curing rate of the first layer may be increased, that is, the curing may become faster. That is, the tact time for forming the first layer may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method of manufacturing an electronic device, the method comprising:
preparing a mold with a first opening defined therein and including a projection portion disposed in the first opening;
forming, in the first opening, a first layer including a first material through an inkjet printing method;
disposing the mold on a display panel in a way such that the first opening faces the display panel; and
forming a display module by removing the mold,
wherein the display module is provided with a second opening defined therein and respectively corresponding to the projection portion.

2. The method of claim 1, wherein the first material comprises a metal.

3. The method of claim 1, further comprising:
forming, on top of the first layer, a second layer including a second material different from the first material, through the inkjet printing method.

4. The method of claim 3, wherein the second material comprises an epoxy-based resin.

5. The method of claim 3, further comprising:
attaching a digitizer film, which detects an external input, to the first layer,
wherein the attaching the digitizer film is performed between the forming the first layer and the forming the second layer.

6. The method of claim 3, further:
comprising forming, on top of the second layer, a third layer including a third material different from the first material and the second material, through the inkjet printing method.

7. The method of claim 6, wherein the third material comprises a colored material.

8. The method of claim 3, further comprising:
attaching a metal layer to the second layer.

9. The method of claim 8, wherein the metal layer comprises copper.

10. The method of claim 1, further comprising:
disposing an electronic module in the second opening,
wherein the disposing the electronic module is performed after the forming the display module.

11. The method of claim 10, wherein the electronic module comprises at least one selected from a camera module, an infrared module, and a fingerprint sensor.

12. The method of claim 1, wherein the forming the first layer in the mold comprises heating the mold at a predetermined temperature.

13. The method of claim 12, wherein the predetermined temperature is in a range of about 80° C. to about 150° C.

14. The method of claim 13, wherein the heating of the mold is performed for about 4 seconds to about 6 seconds.

15. The method of claim 1, wherein the forming the first layer in the mold comprises irradiating the mold with ultraviolet rays.

16. The method of claim 1, wherein a step is formed on an inner surface of the mold defining the first opening.

17. The method of claim 1, wherein when viewed on a plane, a corner of the first opening has a rounded shape.

18. The method of claim 1, wherein
the projection portion is provided in plurality, and
a plurality of projection portions is adjacent to each other.

19. A method of manufacturing an electronic device, the method comprising:
providing a mold having a first opening defined therein;
forming, in the first opening, a first layer including a first material having conductivity through an inkjet printing method;
forming, on top of the first layer, a second layer including a second material different from the first material through the inkjet printing method;
forming, on top of the second layer, a third layer including a third material including a colored material through the inkjet printing method;
attaching the mold to a display panel in a way such that the third layer faces the display panel; and
forming a display module by removing the mold.

20. The method of claim 19, wherein
the mold comprises a projection portion disposed in the first opening,
a second opening corresponding to the projection portion is defined in the display module, and
the method further comprises disposing an electronic module in the second opening.
